(19) United States
(12) Patent Application Publication
(10) Pub. No.: US 2025/0233056 A1
(43) Pub. Date: Jul. 17, 2025

(54) SEMICONDUCTOR DEVICE

(71) Applicant: Mitsubishi Electric Corporation, Tokyo (JP)

(72) Inventor: Hongbo ZHANG, Tokyo (JP)

(73) Assignee: Mitsubishi Electric Corporation, Tokyo (JP)

(21) Appl. No.: 18/948,643

(22) Filed: Nov. 15, 2024

(30) Foreign Application Priority Data
Jan. 16, 2024 (JP) 2024-004340

(51) Int. Cl. H01L 23/495; H01L 23/31; H01L 23/367; H01L 25/07

(52) U.S. Cl. CPC H01L 23/49558; H01L 23/3121; H01L 23/3675; H01L 23/49503; H01L 23/49562; H01L 25/072

(57) ABSTRACT

An object of the present disclosure is to provide a semiconductor device capable of improving reliability. A semiconductor device according to the present disclosure includes an insulating sheet on which one die pad is disposed, an insulating sheet on which a plurality of die pads are disposed, a semiconductor switch and a rectification diode disposed on the die pad, a semiconductor switch and a rectification diode disposed on each die pad, and a heatsink bonded to the insulating sheet and the insulating sheet.

### BACKGROUND OF THE INVENTION

### Field of the Invention

The present disclosure relates to a semiconductor device.

### Description of the Background Art

Disclosed conventionally is a semiconductor device including a converter circuit, a brake circuit, and an inverter circuit (for example, refer to Japanese Patent Application Laid-Open No. 2015-65339). In the semiconductor device disclosed in Japanese Patent Application Laid-Open No. 2015-65339, an insulating sheet made of resin is provided to one surface of a heatsink, a frame is provided on the insulating sheet, and a semiconductor chip and a wire are bonded on the frame. Then, the insulating sheet, the frame, the semiconductor chip, and the wire are sealed by mold resin.

### SUMMARY

Mechanical characteristics are different between a metal member and a resin member. Accordingly, internal stress caused by shrinkage and extension of different types of members occurs by environmental stress such as a temperature and humidity. This internal stress causes detachment of the insulating sheet from the heatsink, and has influence on reliability of the semiconductor device. Stress is easily concentrated in a corner part of the insulating sheet, for example, in the semiconductor device disclosed in Japanese Patent Application Laid-Open No. 2015-65339, thus the insulating sheet is easily detached due to this stress. In this manner, there is room for improvement in reliability in the conventional semiconductor device.

An object of the present disclosure is to provide a semiconductor device capable of improving reliability.

A semiconductor device according to the present disclosure includes: a first insulating material on which one first die pad is disposed; a second insulating material on which a plurality of second die pads are disposed; a first semiconductor element disposed on the first die pad; a second semiconductor element disposed on each of the second die pads; and a heatsink bonded to the first insulating material and the second insulating material.

According to the present disclosure, reliability can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view illustrating an example of a configuration of a semiconductor device according to an embodiment 1.

FIG. 2 is a cross-sectional view illustrating an example of the configuration of the semiconductor device according to the embodiment 1.

FIG. 3 is a cross-sectional view for explaining internal stress in the semiconductor device according to a conventional technique.

FIG. 4 is a plan view for explaining internal stress in the semiconductor device according to the conventional technique.

FIG. 5 is a cross-sectional view for explaining internal stress in the semiconductor device according to the embodiment 1.

FIG. 6 is a cross-sectional view illustrating an example of a configuration of a semiconductor device according to an embodiment 2.

FIG. 7 is a cross-sectional view for explaining internal stress in the semiconductor device according to the embodiment 2.

FIG. 8 is a cross-sectional view illustrating an example of a configuration of a semiconductor device according to an embodiment 3.

FIG. 9 is a cross-sectional view illustrating an example of a configuration of a semiconductor device according to an embodiment 4.

FIG. 10 is a cross-sectional view for explaining internal stress in the semiconductor device according to the embodiment 4.

### DESCRIPTION OF THE PREFERRED EMBODIMENTS

### Embodiment 1

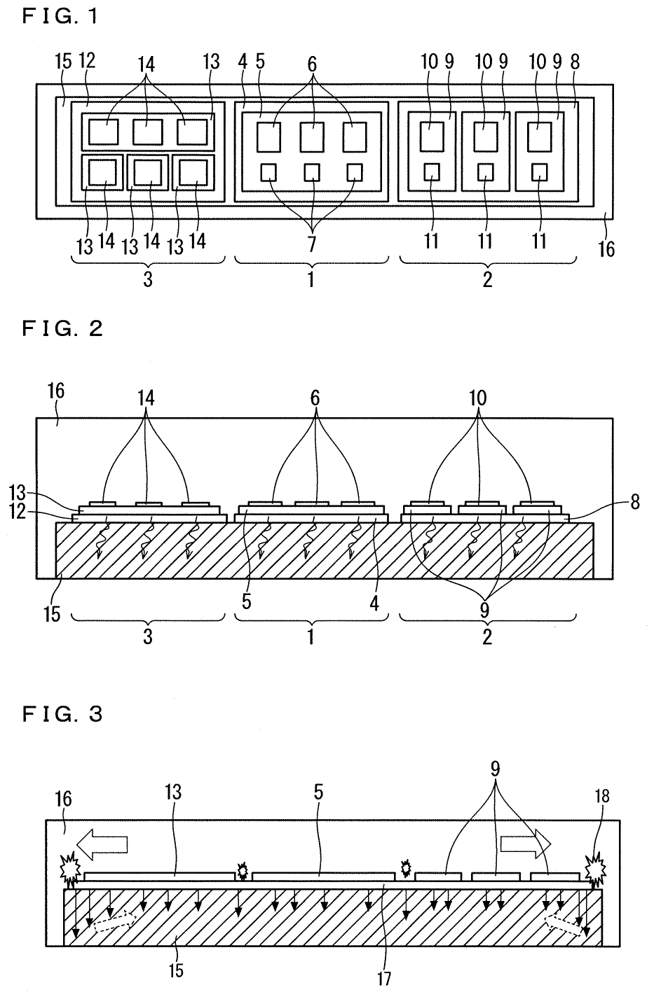

FIG. 1 is a plan view illustrating an example of a configuration of a semiconductor device according to an embodiment 1. FIG. 2 is a cross-sectional view illustrating an example of the configuration of the semiconductor device according to the embodiment 1.

The semiconductor device according to the embodiment 1 includes an inverter circuit and a converter circuit 3. The inverter circuit is made up of an inverter P-side circuit 1 as a high side and an inverter N-side circuit 2 as a low side.

In the inverter P-side circuit 1, one die pad 5 (first die pad) is disposed on one insulating sheet 4 (first insulating material). Three pairs of a semiconductor switch 6 and a rectification diode 7, that is to say, six semiconductor elements (first semiconductor elements) in total are disposed on the die pad 5. The semiconductor switch 6 is an insulated gate bipolar transistor (IGBT), for example. The die pad 5 is made of copper, for example, and is a part of a frame constituting the semiconductor device.

In the inverter N-side circuit 2, three die pads 9 (second die pads) are disposed on one insulating sheet 8 (second insulating material). One pair of a semiconductor switch 10 and a rectification diode 11, that is to say, two semiconductor elements (second semiconductor elements) in total are disposed on one die pad 9. In this manner, six semiconductor elements in total are disposed in a region where one insulating sheet 8 is disposed in the inverter N-side circuit 2 in the manner similar to the inverter P-side circuit 1. Each die pad 9 corresponds to a U phase, a V phase, and a W phase. Three die pads 9 are collectively disposed on the insulating sheet 8, thus cost can be reduced.

In the converter circuit 3, four die pads 13 (third die pads) are disposed on one insulating sheet 12 (third insulating material). Three rectification diodes 14 are disposed on one die pad 13 (P-side converter) in four die pads 13. One rectification diode 14 (corresponding to the U phase, the V phase, or the W phase) is disposed on each of remaining three die pads 13 (N-side converter). In this manner, six semiconductor elements in total are disposed in a region where one insulating sheet 12 is disposed in the converter circuit 3 in the manner similar to the inverter P-side circuit 1 and the inverter N-side circuit 2. The converter circuit 3 can be downsized by reason that the semiconductor switch is not included, thus the converter circuit 3 can solely have substantially the same size as the inverter P-side circuit 1 and the inverter N-side circuit 2. Four die pads 13 are collectively disposed on the insulating sheet 12, thus cost can be reduced.

The insulating sheets 4, 8, and 12 are bonded to a heatsink 15. The heatsink 15 has a function of dissipating heat generated in each of the inverter P-side circuit 1, the inverter N-side circuit 2, and the converter circuit 3 to an outside. The heatsink 15 may be made of a metal material such as aluminum, for example, to improve heat radiation properties.

The mold resin 16 (sealing resin) seals the insulating sheets 4, 8, and 12, the die pads 5, 9, and 13, the semiconductor switches 6 and 10, and the rectification diodes 7, 11, and 13. The mold resin 16 has insulation properties, and may be made of epoxy resin, for example.

It is preferable that an area of the insulating sheet 4 in the inverter P-side circuit 1 is equal to or larger than 90% and equal to or smaller than 110% of an area of the insulating sheet 8 in the inverter N-side circuit 2 in a plan view. The area of the insulating sheet 4 and the area of the insulating sheet 8 are substantially the same as each other, thus planar properties of the insulating sheet 4 and the insulating sheet 8 are substantially the same as each other. Accordingly, internal stress of the semiconductor device can be uniformed, and the semiconductor device having resistance to environmental stress can be achieved.

It is preferable that an area of the insulating sheet 12 in the converter circuit 3 is equal to or larger than 90% and equal to or smaller than 110% of the area of the insulating sheet 4 in the inverter P-side circuit 1 or the area of the insulating sheet 8 in the inverter N-side circuit 2 in a plan view. The area of the insulating sheet 4 and the area of the insulating sheet 12 are substantially the same as each other, thus planar properties of the insulating sheet 4 and the insulating sheet 12 are substantially the same as each other.

Accordingly, internal stress of the semiconductor device can be uniformed, and the semiconductor device having resistance to environmental stress can be achieved.

Although not shown in the diagrams, an optional material such as a wire or an electrode is wired to constitute a circuit in the inverter P-side circuit 1, the inverter N-side circuit 2, and the converter circuit 3.

Although not shown in the diagrams, each of the inverter P-side circuit 1, the inverter N-side circuit 2, and the converter circuit 3 includes an external terminal to be electrically connected to the outside. The mold resin 16 seals the inverter P-side circuit 1, the inverter N-side circuit 2, and the converter circuit 3 to expose the external terminal to the outside. Each of the inverter P-side circuit 1, the inverter N-side circuit 2, and the converter circuit 3 outputs current or a control signal outside the mold resin 16 via the external terminal.

Although not shown in the diagrams, the semiconductor device according to the embodiment 1 may further include a brake circuit. In this case, it is sufficient that the semiconductor device includes a pair of the semiconductor switch and the rectification diode constituting the brake circuit. The brake circuit may be included in any of the insulating sheet 4 in the inverter P-side circuit 1, the insulating sheet 8 in the inverter N-side circuit 2, and the insulating sheet 12 in the converter circuit 3, but is preferably included in the insulating sheet 12 in the converter circuit 3.

The insulating sheet 4, the insulating sheet 8, and the insulating sheet 12 are firmly attached with no gap between the heatsink 15 and the die pad 5 in the inverter P-side circuit 1, the die pad 9 in the inverter N-side circuit 2, and the die pad 13 in the converter circuit 3, respectively, thus a heat radiation route having low heat resistance is ensured in a vertical direction in FIG. 2 (wavy arrow in FIG. 2). Herein, the die pad 5, the die pad 9, and the die pad 13 are also referred to as concentration heat radiation die pads. The concentration heat radiation die pads may be disposed at intervals so as not to thermally interfere with each other.

The insulating sheets 4, 8, and 12 are separately disposed in accordance with each concentration heat radiation die pad. A width of a region of separating the insulating sheets 4, 8, and 12 is smaller than a distance between the concentration heat radiation die pads, thus an insulating distance between the concentration heat radiation die pad and the heatsink 15 is ensured.

Heat is generated in roughly the inverter P-side circuit 1, the inverter N-side circuit 2, and the converter circuit 3 in the operation of the semiconductor device. The semiconductor element belonging to each of these circuits has a similar behavior in a single body, thus a heat generation amount thereof is substantially the same. However, a behavior of each semiconductor element is different for each circuit, thus a heat generation amount in each circuit is different. Accordingly, thermal interference may occur between the circuits as heat generation sources. For example, heat is transmitted from the inverter P-side circuit 1 to the inverter N-side circuit 2 and the converter circuit 3 via the heatsink 15. Transmission of heat in reverse may also occur.

It is ideal to transmit heat in a vertical direction without thermal interference with the adjacent die pad as much as possible to efficiently dissipate heat generated in the semiconductor device to the outside In the semiconductor device according to the embodiment 1, reduced is interference of heat generated in each of the inverter P-side circuit 1, the inverter N-side circuit 2, and the converter circuit 3, and ensured is a heat radiation route of heat transmitted to the heatsink 15 via the insulating sheet immediately below the die pad. Accordingly, unevenness of a temperature distribution in the insulating sheet caused by unevenness of heat generation in the semiconductor element can be suppressed.

A linear expansion coefficient of each material constituting the semiconductor device is uneven, thus occurrence of warpage of the semiconductor device due to the environmental stress cannot be prevented. The environmental stress includes a temperature gradient by heat generated in the semiconductor element constituting the semiconductor device, an external temperature change, and humidity, for example. When the semiconductor device receives the environmental stress, internal stress occurs by reason that relative positional variation tends to occur between the die pads 5, 9, and 13, the insulating sheets 4, 8, and 12, the heatsink 15, and the mold resin 16. Particularly, when stress occurs in a bonding interface between the insulating sheets 4, 8, and 12 and the heatsink 15 and a bonding interface between the insulating sheets 4, 8, and 12 and the die pads 5, 9, and 13, the insulating sheets 4, 8, and 12 are detached, and this detachment gradually spreads to eventually lead to a whole surface detachment.

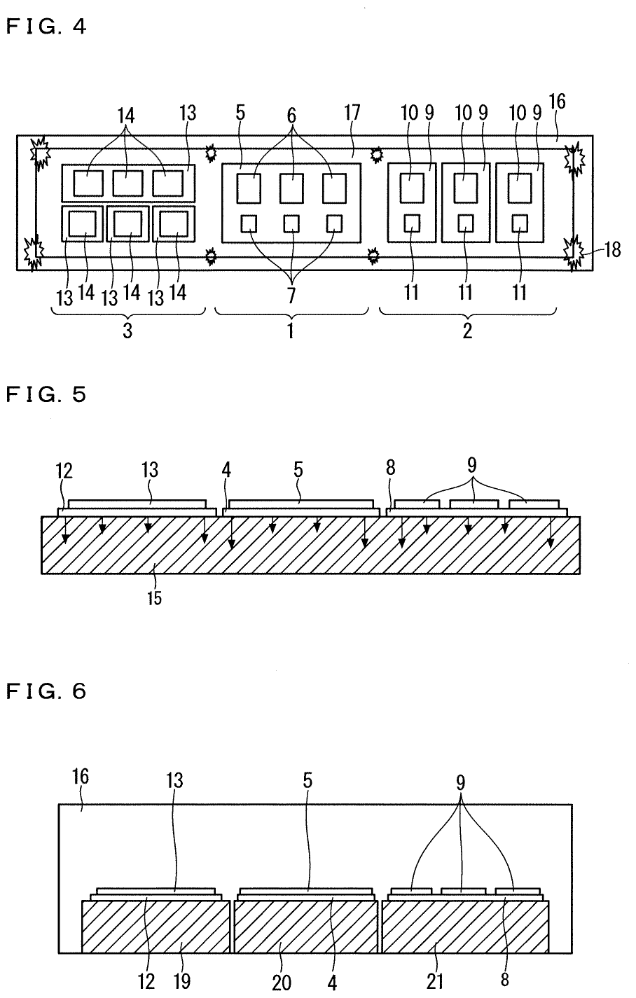

FIG. 3 is a cross-sectional view for explaining internal stress in a semiconductor device according to a conventional technique. FIG. 4 is a plan view for explaining internal stress in the semiconductor device according to the conventional technique. Illustration of the semiconductor element is omitted in FIG. 3. One insulating sheet 17 is disposed on the heatsink 15 in the semiconductor device according to the conventional technique. In FIG. 3, an open arrow indicates a direction of stress, and a black arrow indicates strength of internal stress.

As illustrated in FIGS. 3 and 4, stress is concentrated in an end portion such as a corner part and a side part of the insulating sheet 17 more easily than a center part thereof, thus such an end portion often serves as a detachment start point 18. As a size of the semiconductor device gets larger, warpage occurs more easily, and the internal stress also increases.

In the meanwhile, in the semiconductor device according to the embodiment 1, as illustrated in FIG. 5, internal stress caused by whole warpage is locally applied to each of the insulating sheet 4 in the inverter P-side circuit 1, the insulating sheet 8 in the inverter N-side circuit 2, and the insulating sheet 12 in the converter circuit 3. However, in the semiconductor device according to the embodiment 1, each of the insulating sheets 4, 8, and 12 does not pull each other compared with one insulating sheet 17 included in the semiconductor device (refer to FIGS. 3 and 4) according to the conventional technique, thus stress in the end portions of the insulating sheets 4, 8, and 12 and a gap part between the die pads 5, 9, and 13 is reduced. Accordingly, the detachment of the insulating sheets 4, 8, and 12 can be prevented without breakage of the bonding interface between the heatsink 15 and the insulating sheets 4, 8, and 12. Illustration of the semiconductor element is omitted in FIG. 5.

Also considered is a method of increasing bonding strength using an insulating sheet as a resin component having high adhesiveness, however, cost also increases or the other characteristics are sacrificed, thus a degree of difficulty is technically high. According to the embodiment 1, the semiconductor device having high reliability can be achieved while diverting an existing material.

### Embodiment 2

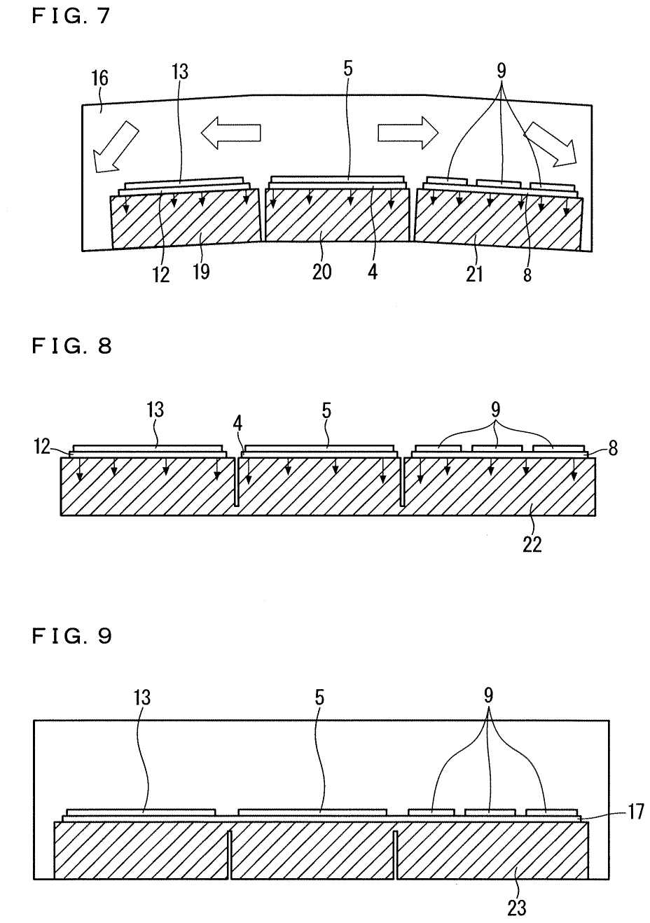

FIG. 6 is a cross-sectional view illustrating an example of a configuration of a semiconductor device according to an embodiment 2.

As illustrated in FIG. 6, the semiconductor device according to the embodiment 2 has a feature that three heatsinks 19, 20, and 21 are divided in regions between the insulating sheets 4, 8, and 12. Illustration of the semiconductor element is omitted in FIG. 6, however, the configuration is similar to the embodiment 1 (refer to FIGS. 1 and 2).

Specifically, the heatsinks 19 and 20 are divided in a region between the insulating sheets 4 and 12. The heatsinks 20 and 21 are divided in a region between the insulating sheets 4 and 8.

FIG. 7 is a cross-sectional view for explaining internal stress in the semiconductor device according to the embodiment 2. Illustration of the semiconductor element is omitted in FIG. 7, however, the configuration is similar to the embodiment 1 (refer to FIGS. 1 and 2). In FIG. 7, an open arrow indicates a direction of stress, and a black arrow indicates strength of internal stress.

In the operation of the semiconductor device, the mold resin 16 is expanded by absorbing moisture from environment, however, the heatsink 15 is hardly expanded. In the semiconductor device according to the embodiment 2, three heatsinks 19, 20, and 21 are divided, thus even when the mold resin 16 is expanded and the semiconductor device warps, the divided heatsinks 19, 20, and 21 easily follow an expansion direction of the mold resin 16, and the stress on the insulating sheets 4, 8, and 12 is reduced. As a result, the detachment of the insulating sheets 4, 8, and 12 can be prevented without breakage of the bonding interface between the insulating sheets 4, 8, and 12 and the heatsinks 19, 20, and 21.

### Embodiment 3

FIG. 8 is a cross-sectional view illustrating an example of a configuration of a semiconductor device according to the embodiment 3.

As illustrated in FIG. 8, the semiconductor device according to the embodiment 3 has a feature that a heatsink 22 is formed into a comb-like shape. Illustration of the semiconductor element is omitted in FIG. 8, however, the configuration is similar to the embodiment 1 (refer to FIGS. 1 and 2). In FIG. 8, a black arrow indicates strength of internal stress.

Specifically, the heatsink 22 includes a depression (groove) in a region between the insulating sheet 4 and the insulating sheet 8 and a region between the insulating sheet 4 and the insulating sheet 12. This depression is provided to a side of a surface of the heatsink 22 to which the insulating sheets 4, 8, and 12 are bonded.

According to such a configuration, as with the semiconductor device according to the embodiment 2, the heatsink 22 easily follows the warpage of the semiconductor device due to temperature change or moisture absorption, and the heatsink 22 is continuously formed with one metal plate, thus such a configuration can contribute to simplification of an assembly process without increasing the number of components.

### Embodiment 4

FIG. 9 is a cross-sectional view illustrating an example of a configuration of a semiconductor device according to an embodiment 4.

As illustrated in FIG. 9, the semiconductor device according to the embodiment 4 has a feature that a heatsink 23 is formed into a comb-like shape. Illustration of the semiconductor element is omitted in FIG. 9, however, the configuration is similar to the embodiment 1 (refer to FIGS. 1 and 2).

Specifically, the heatsink 23 includes a depression (groove) on both sides facing a surface to which the insulating sheet 17 is bonded.

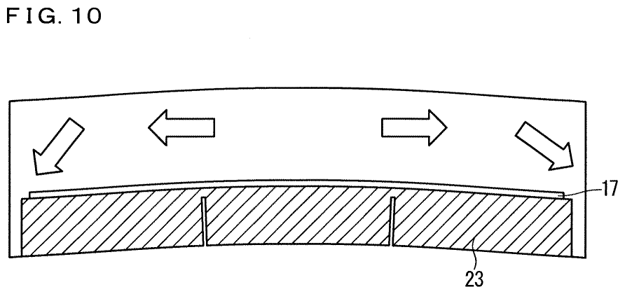

In the semiconductor device according to the conventional technique as illustrated in FIG. 3, when the mold resin 16 absorbs moisture and is expanded, the heatsink 15 has resistance against the expansion thereof, thus stress is applied to the insulating sheet 17. In the meanwhile, in the semiconductor device according to the embodiment 4, the depression is provided to the heatsink 23 as illustrated in FIG. 10, thus the heatsink 23 easily warps along the expansion direction of the mold resin 16, and obtained is an effect of reducing internal stress of the semiconductor device. In FIG. 10, an open arrow indicates a direction of stress. Illustration of the semiconductor element and the die pad is omitted in FIG. 10, however, the configuration is similar to the embodiment 1 (refer to FIGS. 1 and 2).

In the semiconductor device according to the embodiment 4, the insulating sheet 17 may be divided into the insulating sheets 4, 8, and 12 as with the semiconductor device according to the embodiment 1. Specifically, the heatsink 23 includes a depression (groove) in a region between the insulating sheet 4 and the insulating sheet 8 and a region between the insulating sheet 4 and the insulating sheet 12. This depression is provided to a side of a surface of the heatsink 23 facing the surface to which the insulating sheets 4, 8, and 12 are bonded. In this case, the internal stress can be further reduced. However, a similar effect can be expected even in a case where one insulating sheet 17 is used. When the insulating sheet 17 is divided into the insulating sheets 4, 8, 12, a division position of the insulating sheets 4, 8, and 12 and a position of the depression in the heatsink need not necessarily coincide with each other. The heatsink 23 may include two or more depressions.

### <Modification Example of Embodiments 1 to 4>

Described in the embodiments 1 to 4 is the case where the insulating sheet is used as the member for insulating each circuit of the inverter P-side circuit 1, the inverter N-side circuit 2, and the converter circuit 3 from outside, however, the member is not limited to the insulating sheet as long as the member can insulate the circuit from outside. For example, an insulating substrate made of ceramic may be used as a member for insulating the circuit from outside.

Each embodiment can be arbitrarily combined, or each embodiment can be appropriately varied or omitted within the scope of the present disclosure.

### APPENDIX

The aspects of the present disclosure are collectively described hereinafter as appendixes.

### Appendix 1

A semiconductor device, comprising:
a first insulating material on which one first die pad is disposed;
a second insulating material on which a plurality of second die pads are disposed;
a first semiconductor element disposed on the first die pad;
a second semiconductor element disposed on each of the second die pads; and
a heatsink bonded to the first insulating material and the second insulating material.

### Appendix 2

The semiconductor device according to Appendix 1, wherein
at least three of the second die pads are disposed on the second insulating material.

### Appendix 3

The semiconductor device according to Appendix 1 or 2, wherein
an area of the first insulating material is equal to or larger than 90% and equal to or smaller than 110% of an area of the second insulating material in a plan view.

### Appendix 4

The semiconductor device according to any one of Appendixes 1 to 3, further comprising
a third insulating material on which a plurality of second die pads are disposed, wherein
the heatsink is bonded to the third insulating material.

### Appendix 5

The semiconductor device according to Appendix 4, wherein
at least four of the third die pads are disposed on the third insulating material.

### Appendix 6

The semiconductor device according to Appendix 4 or 5, wherein
an area of the third insulating material is equal to or larger than 90% and equal to or smaller than 110% of an area of the first insulating material or the second insulating material in a plan view.

### Appendix 7

The semiconductor device according to any one of Appendixes 1 to 6, wherein
the heatsink includes a depression in a region between the first insulating material and the second insulating material.

### Appendix 8

The semiconductor device according to Appendix 7, wherein
the depression is provided to a side of a surface of the heatsink to which the first insulating material and the second insulating material are bonded.

### Appendix 9

The semiconductor device according to Appendix 7, wherein
the depression is provided to a side of another surface of the heatsink facing the surface of the heatsink to which the first insulating material and the second insulating material are bonded.

### Appendix 10

The semiconductor device according to any one of Appendixes 4 to 6, further comprising
an insulative sealing resin sealing the first insulating material, the second insulating material, the third insulating material, the first die pad, the second die pad, the third die pad, the first semiconductor element, and the second semiconductor element.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a first insulating material on which one first die pad is disposed;
a second insulating material on which a plurality of second die pads are disposed;
a first semiconductor element disposed on the first die pad;
a second semiconductor element disposed on each of the second die pads; and
a heatsink bonded to the first insulating material and the second insulating material.

2. The semiconductor device according to claim 1, wherein
at least three of the second die pads are disposed on the second insulating material.

3. The semiconductor device according to claim 1, wherein
an area of the first insulating material is equal to or larger than 90% and equal to or smaller than 110% of an area of the second insulating material in a plan view.

4. The semiconductor device according to claim 1, further comprising
a third insulating material on which a plurality of third die pads are disposed, wherein
the heatsink is bonded to the third insulating material.

5. The semiconductor device according to claim 2, further comprising
a third insulating material on which a plurality of third die pads are disposed, wherein
the heatsink is bonded to the third insulating material.

6. The semiconductor device according to claim 4, wherein
at least four of the third die pads are disposed on the third insulating material.

7. The semiconductor device according to claim 5, wherein
at least four of the third die pads are disposed on the third insulating material.

8. The semiconductor device according to claim 4, wherein
an area of the third insulating material is equal to or larger than 90% and equal to or smaller than 110% of an area of the first insulating material or the second insulating material in a plan view.

9. The semiconductor device according to claim 5, wherein
an area of the third insulating material is equal to or larger than 90% and equal to or smaller than 110% of an area of the first insulating material or the second insulating material in a plan view.

10. The semiconductor device according to claim 1, wherein
the heatsink includes a depression in a region between the first insulating material and the second insulating material.

11. The semiconductor device according to claim 2, wherein
the heatsink includes a depression in a region between the first insulating material and the second insulating material.

12. The semiconductor device according to claim 3, wherein
the heatsink includes a depression in a region between the first insulating material and the second insulating material.

13. The semiconductor device according to claim 10, wherein
the depression is provided to a side of a surface of the heatsink to which the first insulating material and the second insulating material are bonded.

14. The semiconductor device according to claim 11, wherein
the depression is provided to a side of a surface of the heatsink to which the first insulating material and the second insulating material are bonded.

15. The semiconductor device according to claim 12, wherein
the depression is provided to a side of a surface of the heatsink to which the first insulating material and the second insulating material are bonded.

16. The semiconductor device according to claim 10, wherein
the depression is provided to a side of another surface of the heatsink facing the surface of the heatsink to which the first insulating material and the second insulating material are bonded.

17. The semiconductor device according to claim 11, wherein
the depression is provided to a side of another surface of the heatsink facing the surface of the heatsink to which the first insulating material and the second insulating material are bonded.

18. The semiconductor device according to claim 12, wherein
the depression is provided to a side of another surface of the heatsink facing the surface of the heatsink to which the first insulating material and the second insulating material are bonded.

19. The semiconductor device according to claim 4, further comprising
an insulative sealing resin sealing the first insulating material, the second insulating material, the third insulating material, the first die pad, the second die pad, the third die pad, the first semiconductor element, and the second semiconductor element.

20. The semiconductor device according to claim 5, further comprising
an insulative sealing resin sealing the first insulating material, the second insulating material, the third insulating material, the first die pad, the second die pad, the third die pad, the first semiconductor element, and the second semiconductor element.
